(19) United States
(12) Patent Application Publication
(10) Pub. No.: US 2012/0326307 A1
(43) Pub. Date: Dec. 27, 2012

(54) STACKED SEMICONDUCTOR DEVICE

(76) Inventors: Se-young JEONG, Suwon-si (KR); Sang-sick PARK, Seoul (KR); Tae-gyeong CHUNG, Suwon-si (KR); Tae-je CHO, Hwaseong-si (KR)

(21) Appl. No.: 13/534,792

(22) Filed: Jun. 27, 2012

(30) Foreign Application Priority Data
Jun. 27, 2011 (KR) 10-2011-0062479

(51) Int. Cl. H01L 23/538; H01L 25/07

(52) U.S. Cl. 257/738; 257/777; 257/E25.018; 257/E23.169

(57) ABSTRACT

A stacked semiconductor device including a plurality of semiconductor chips stacked vertically, a plurality of scribe lane elements each forming a step with a semiconductor chip of the plurality of semiconductor chips and respectively formed on a side surface of each of the plurality of semiconductor chips, a redistribution element respectively formed on each of the plurality of semiconductor chips and the scribe lane elements, and a signal connection member formed on the side surface of each of the plurality of semiconductor chips and electrically connecting the redistribution elements.

### CROSS-REFERENCE TO RELATED APPLICATIONS

This application claims the benefit of Korean Patent Application No. 10-2011-0062479, filed on Jun. 27, 2011, in the Korean Intellectual Property Office, the disclosure of which is incorporated by reference herein in its entirety.

### TECHNICAL FIELD

The embodiments of the inventive concept relates to a semiconductor device, and more particularly, to a stacked semiconductor device.

### DISCUSSION OF RELATED ART

In general, a plurality of semiconductor chips are formed by performing various semiconductor processes on a wafer. A semiconductor package is formed by performing a packaging process on the wafer to mount the semiconductor chips on a printed circuit board (PCB). The semiconductor package may include a semiconductor chip, a PCB on which the semiconductor chip is mounted, a bonding wire or a bump that electrically connects the semiconductor chip and the PCB, and a sealing member that seals the semiconductor chip.

With higher integration of semiconductor chips, the semiconductor chips have become smaller in size/ Accordingly semiconductor packages have also become smaller in size. For example, a chip scale package (CSP) or a wafer level package (WLP), etc. may be the same size as the semiconductor chip.

### SUMMARY

Embodiments of the inventive concept provide a stacked semiconductor device that allows for a reduction in processing time taken to form a signal connection member that electrically connects a plurality of stacked semiconductor chips.

According to an embodiment of the inventive concept, there is provided a stacked semiconductor device including a plurality of semiconductor chips stacked on each other, a plurality of scribe lanes element each forming a step with a semiconductor chip of the plurality of semiconductor chips and respectively formed on a side surface of each of the plurality of semiconductor chips, a redistribution element respectively formed on each of the plurality of semiconductor chips and the scribe lane elements, and a signal connection member formed on the side surface of each of the plurality of semiconductor chips and electrically connecting the redistribution elements.

The plurality of semiconductor chips may be homogeneous or heterogeneous with each other.

The redistribution elements may cover at least one pad formed in a surface of each of the plurality of semiconductor chips and be respectively electrically connected to each of the plurality of semiconductor chips.

The redistribution elements may be electro plating layers or electroless plating layers.

The thickness of the redistribution elements on the scribe lane elements may be greater than thickness of the redistribution elements on each of the plurality of semiconductor chips.

The signal connection member may be an electroless plating layer.

The plurality of semiconductor chips may be mounted on a substrate, the signal connection member contacts the substrate, and the plurality of semiconductor chips and the substrate are electrically connected.

The substrate may include an external connection terminal connected to an external device.

The external connection terminal may be a solder ball.

The stacked semiconductor device may further include an adhesive layer formed on each of the plurality of semiconductor chips and adhering the plurality of semiconductor chips that are stacked vertically to each other.

According to an embodiment of the inventive concept, there is provided a stacked semiconductor device including a first semiconductor chip including a scribe lane element having a step on a side surface of the first semiconductor chip and at least one pad connected to an integrated circuit (IC) in an active surface of the first semiconductor chip, a first redistribution element formed on the first semiconductor chip, at least one second semiconductor chip including a second scribe lane element having a step on a side surface of the second semiconductor chip and at least one pad connected to an IC in an active surface of the at least one second semiconductor chip, a second redistribution element formed on the at least one second semiconductor chip and a signal connection member for electrically connecting the first redistribution element and the second redistribution element.

The first redistribution element and the second redistribution element may be electro plating layers or electroless plating layers.

A thickness of the first redistribution element formed on the first scribe lane element may be greater than a thickness of the first redistribution element formed on the active surface of the first semiconductor chip.

A thickness of the second redistribution element formed on the second scribe lane element may be greater than a thickness of the second redistribution element formed on the active surface of the second semiconductor chip.

The signal connection member may be an electroless plating layer.

A stacked semiconductor device, according to an embodiment of the inventive concept, comprises a first semiconductor chip comprising a first scribe lane element forming a step with a side surface of the first semiconductor chip, a first redistribution element formed on a top surface of the first semiconductor chip and extending onto the first scribe lane element, at least one second semiconductor chip stacked on the first semiconductor chip and comprising a second scribe lane element forming a step with a side surface of the second semiconductor chip, a second redistribution element formed on a top surface of the at least one second semiconductor chip and extending onto the second scribe lane element; and a signal connection member for electrically connecting the first redistribution element with the second redistribution element.

A width of the first scribe lane element may be greater than a width of the second scribe lane element. A width of the first redistribution element on the first scribe lane element may be greater than a width of the second redistribution element on the second scribe lane element. The widths of the first and second redistribution elements on the first and second scribe lane elements may respectively correspond to the widths of the first and second scribe lane elements.

The first and second redistribution elements may respectively cover at least one pad formed in the top surface of each of the first and second semiconductor chips and be respectively electrically connected to the first and second semiconductor chips.

### BRIEF DESCRIPTION OF THE DRAWINGS

Exemplary embodiments of the inventive concept will be more clearly understood from the following detailed description taken in conjunction with the accompanying drawings in which:

FIG. 1 is a perspective view illustrating a stacked semiconductor device according to an embodiment of the inventive concept;

FIG. 2 is a perspective view illustrating a stacked semiconductor device according to an embodiment of the inventive concept;

FIG. 3 is a plan view of a semiconductor chip formed on a wafer before the semiconductor chip is sawed according to an embodiment of the inventive concept;

FIGS. 4A through 4L are cross-sectional views illustrating a method of manufacturing a stacked semiconductor device according to an embodiment of the inventive concept;

FIGS. 5A through 5E are cross-sectional views illustrating a method of manufacturing a stacked semiconductor device according to an embodiment of the inventive concept;

FIGS. 6A through 6G are cross-sectional views illustrating a method of manufacturing a stacked semiconductor device according to an embodiment of the inventive concept;

FIG. 7 is a cross-sectional view illustrating heights of redistribution elements in which a signal connection member is formed according to an embodiment of the inventive concept;

FIG. 8A is a plan view of a semiconductor module including a stacked semiconductor device according to an embodiment of the inventive concept;

FIG. 8B is a block diagram of an electronic circuit board according to an embodiment of the inventive concept; and

FIG. 8C is a block diagram of an electronic system according to an embodiment of the inventive concept.

### DETAILED DESCRIPTION OF EMBODIMENTS

Embodiments of the inventive concept will be described more fully with reference to the accompanying drawings, in which exemplary embodiments of the inventive concept are shown. This inventive concept may, however, be embodied in many different forms and should not construed as limited to the exemplary embodiments set forth herein. Like reference numerals in the drawings may denote like elements. In the drawings, various elements and regions are schematically drawn. Therefore, the embodiments of the inventive concept are not necessarily limited to the relative sizes and gaps depicted in the accompanying drawings.

The singular forms can include the plural forms unless the context clearly indicates otherwise.

It will be understood that when an element or layer is referred to as being “on,” “connected to” or “coupled to” another element or layer, it can be directly on, connected or coupled to the other element or layer or intervening elements or layers may be present.

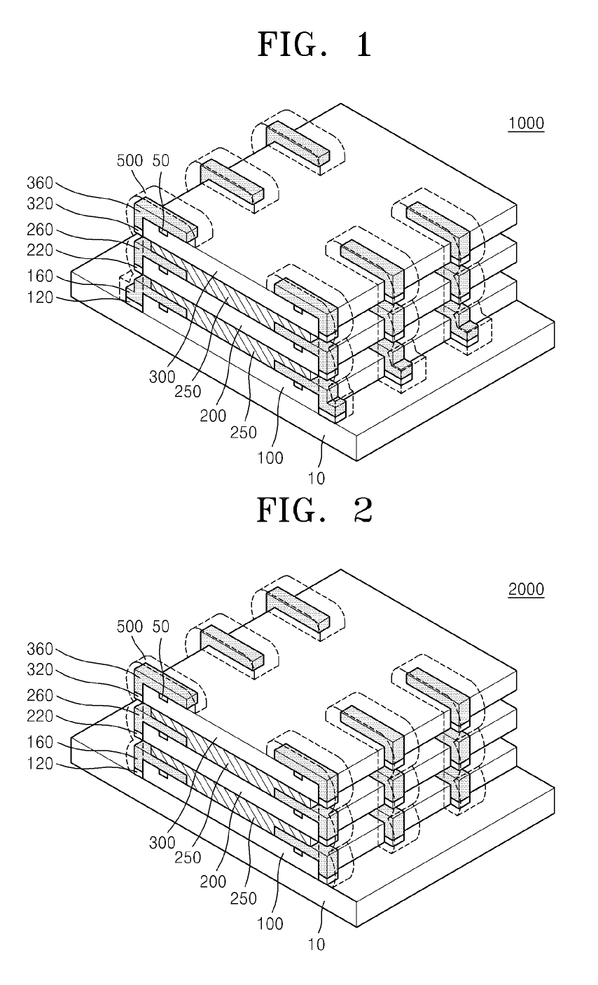

FIG. 1 is a perspective view illustrating a stacked semiconductor device 1000 according to an embodiment of the inventive concept. Referring to FIG. 1, the stacked semiconductor device 1000 includes a plurality of semiconductor chips 100, 200, and 300, scribe lane elements 120, 220, and 320, and redistribution elements 160, 260, and 360, and a signal connection member 500.

According to an embodiment, a substrate 10 includes a top surface and a bottom surface. The top surface includes a first metal wire (not shown). The first metal wire is a circuit pattern formed on the substrate 10. The circuit pattern can include metal wires such as copper.

According to an embodiment, the substrate 10 includes an external connection terminal (not shown) on the bottom surface thereof. The external connection terminal connects the stacked semiconductor device 1000 to elements outside of the semiconductor device. The substrate 100 can be, for example, a printed circuit board (PCB) substrate. The external connection terminal can be, for example, a solder ball. According to an embodiment, the solder ball can be formed in a solder ball land (not shown) at the bottom surface of the substrate 10. The semiconductor chips 100, 200, and 300 stacked on the substrate 10 can be electrically connected to the substrate 10 through a connection element (not shown). The connection element can be, for example, wire bonding used to electrically connect the semiconductor chips 100, 200, and 300 and the substrate 10, or a contact(s) passing through the semiconductor chips 100, 200, and 300 and electrically connected to the substrate 10. However, the embodiments of the inventive concept are not limited thereto.

According to an embodiment, the semiconductor chips 100, 200, and 300 stacked vertically are disposed on the substrate 10, and include integrated circuits (ICs) therein. For example, the ICs include memory circuits or logic circuits. The semiconductor chips 100, 200, and 300 have active surfaces and non-active surfaces facing the active surfaces. According to an embodiment, an adhesive layer (not shown) facing the substrate 10 is formed in the non-active surfaces of the semiconductor chips 100, 200, and 300. At least one pad 50 respectively connected to the ICs is formed in the active surfaces. The pad 50 can be formed of a metal such as aluminium (Al), copper (Cu), silver (Ag), gold (Au), or palladium (Pd), etc.

The stacked semiconductor chips 100, 200, and 300 can be homogeneous or heterogeneous products. For example, some of the semiconductor chips 100, 200, and 300 are memory chips, and others are non-memory chips. According to an embodiment, the semiconductor chips 100, 200, and 300 are all memory chips. The semiconductor chips 100, 200, and 300 can include flash memory, phase-change random access memory (PRAM), resistive RAM (RRAM), ferroelectric RAM (FeRAM), magnetoresistive (MRAM), etc.

The semiconductor chips 100, 200, and 300 can have the same size or different sizes according to the types of memory circuits. That is, although the semiconductor chips 100, 200, and 300 having the same width are stacked vertically as shown in FIG. 1, the embodiments of the inventive concept are not limited thereto, and semiconductor chips having different sizes may be stacked or a plurality of semiconductor chips may be offset from each other and stacked.

The number of the semiconductor chips 100, 200, and 300 shown is exemplary and is not limited thereto.

The scribe lane elements 120, 220, and 320 are stepped regions formed on one or more side surfaces of each of the semiconductor chips 100, 200, and 300.

The scribe lane elements 120, 220, and 320 are regions where a sawing or other type of cutting process is performed to separate semiconductor chips formed on a wafer. According to an embodiment, the steps between the scribe lane elements 120, 220, and 320 and the semiconductor chips 100, 200, and 300 are formed by performing an etching process on the scribe lane elements 120, 220, and 320 before the sawing or other type of cutting process is performed. According to an embodiment, the steps between the scribe lane elements 120, 220, and 320 and the semiconductor chips 100, 200, and 300 increase thicknesses of the redistribution elements 160, 260, and 360 formed on the scribe lane elements 120, 220, and 320, and increase areas of the redistribution elements 160, 260, and 360 that are exposed to the area outside of the semiconductor chips.

As a result of the increased areas of the redistribution elements, gaps between the semiconductor chips 100, 200, and 300 that are stacked vertically and the redistribution elements 160, 260, and 360 may be reduced, thereby reducing a processing time required to form the signal connection member(s) 500 that electrically connect the redistribution elements 160, 260, and 360.

According to an embodiment, the redistribution elements 160, 260, and 360 are formed on the semiconductor chips 100, 200, and 300 and on the on the scribe lane elements 120, 220, and 320.

The redistribution elements 160, 260, and 360, which are wire patterns used to re-arrange the pads 50, can be formed to cover the pads 50 formed in the semiconductor chips 100, 200, and 300. The redistribution elements 160, 260, and 360 can be used to electrically connect a semiconductor chip 100 to an external substrate or to other semiconductor chips through the pads 50. The redistribution elements 160, 260, and 360 can be formed by using electroplating or electroless plating.

According to an embodiment, depending on the number of semiconductor chips in a stack, adhesive layers 250 for stacking the semiconductor chips 100, 200, and 300 are formed on the semiconductor chips 100, 200, and 300 and the redistribution elements 160, 260, and 360.

The signal connection members 500 are formed on side surfaces of the semiconductor chips 100, 200, and 300 and electrically connect the semiconductor chips 100, 200, and 300. More specifically, the signal connection members 500 are formed on the semiconductor chips 100, 200, and 300 and the scribe lane elements 120, 220, and 320, and are formed on the redistribution elements 160, 260, and 360 that are exposed to an outside of the semiconductor chips. The signal connection members are formed by generating and growing an electroless plating layer, thereby electrically connecting the semiconductor chips 100, 200, and 300 that are stacked vertically.

FIG. 2 is a perspective view illustrating a stacked semiconductor device 2000 according to an embodiment of the inventive concept.

In the stacked semiconductor device 1000 of FIG. 1, the redistribution elements 160 are formed on the semiconductor chip 100 on a wafer, the semiconductor chips 200 and 300 including the redistribution elements 260 and 360 are stacked on the semiconductor chip 100, the signal connection members 500 are formed on side surfaces of the semiconductor chips 100, 200, and 300, and a semiconductor device that is sawed using a sawing process is formed on the substrate 10.

In the stacked semiconductor device 2000 of FIG. 2, the already sawed semiconductor chips 100, 200, and 300 in which the redistribution elements 160, 260, and 360 are formed are sequentially stacked on the substrate 10, and the signal connection members 500 are formed on the side surfaces of the semiconductor chips 100, 200, and 300.

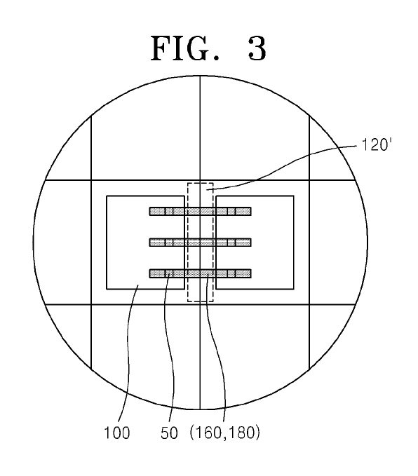

FIG. 3 is a plan view of the semiconductor chip 100 formed on a wafer before the semiconductor chip 100 is sawed or cut by some other process, according to an embodiment of the inventive concept.

Referring to FIG. 3, the at least one pad 50 is formed on an active surface of the semiconductor chip 100, and redistribution elements 160 and 180 are formed on a scribe lane element 120′ used when sawing the semiconductor chip 100.

The redistribution elements 160 and 180, which are wire patterns used to re-arrange the pads 50, are formed to cover the pads 50 formed in the semiconductor chip 100. The redistribution elements 160 and 180 can be used to electrically connect the semiconductor chip 100 to an external substrate or to other semiconductor chips through the pads 50.

According to an embodiment, before the redistribution elements 160 and 180 are formed, an etching process is performed on a region, i.e. the scribe lane element 120′, where a sawing process is performed on the semiconductor chip 100 formed on the wafer. As a result, a step between the scribe lane element 120′ and the semiconductor chip 100 is formed, thereby reducing a processing time taken to form the signal connection members 500 (see FIG. 1).

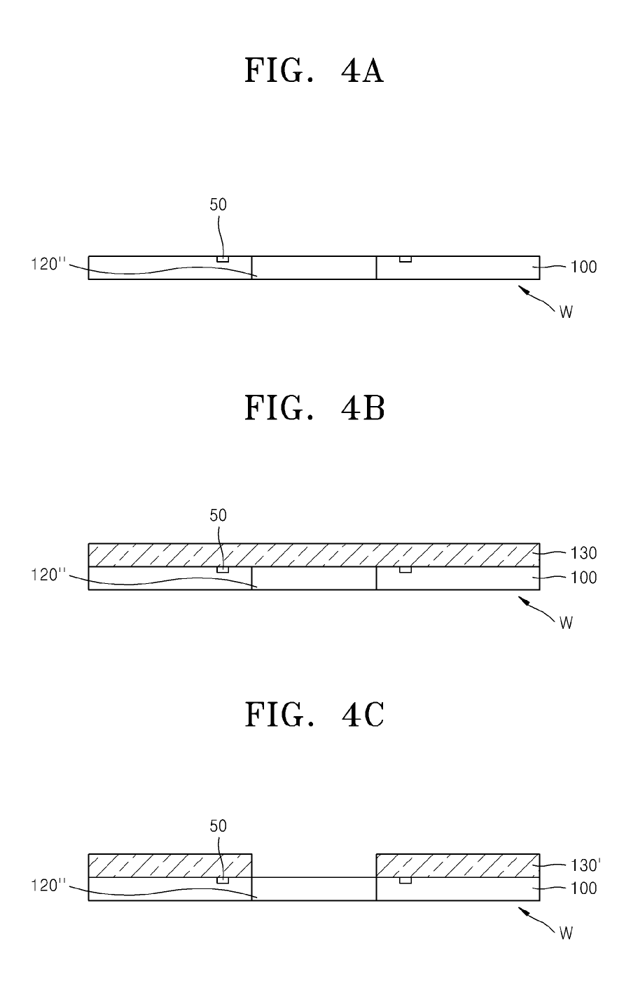

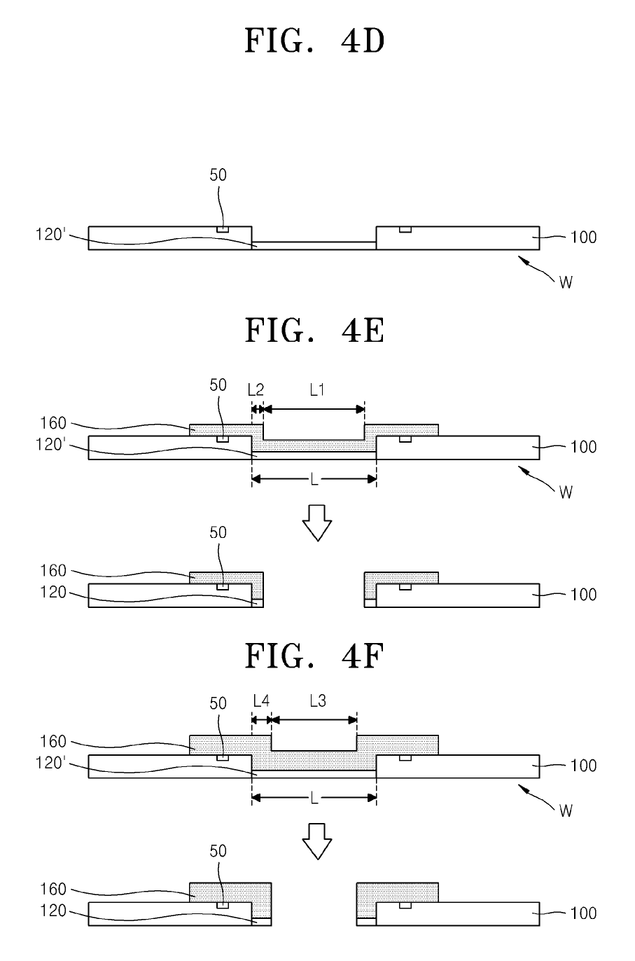

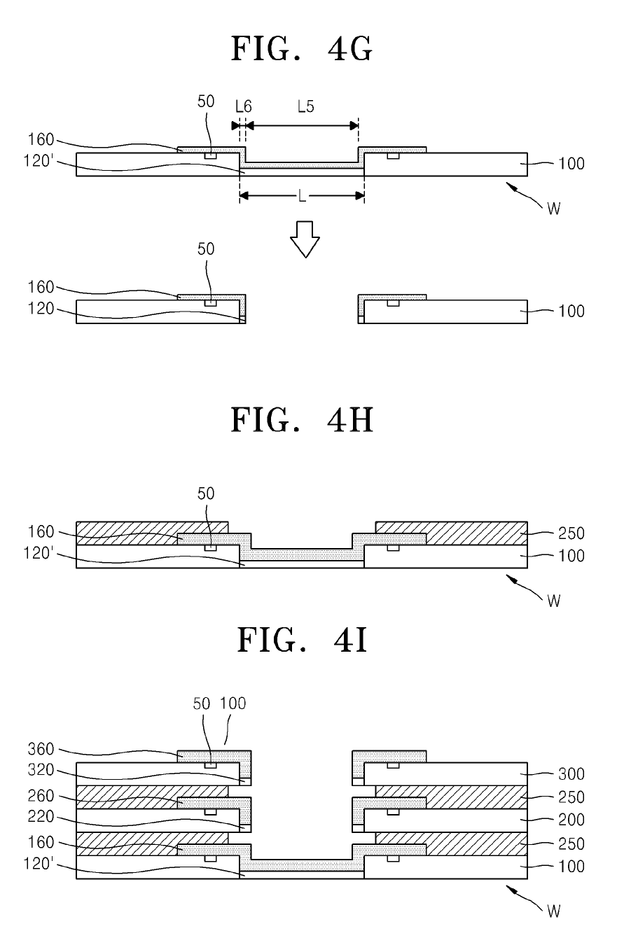

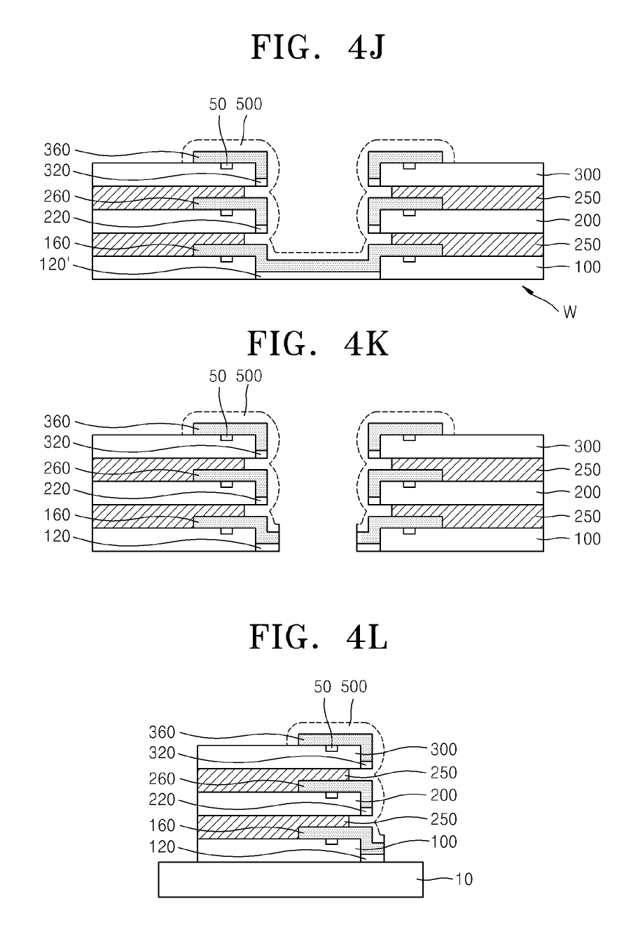

FIGS. 4A through 4L are cross-sectional views illustrating a method of manufacturing a stacked semiconductor device according to an embodiment of the inventive concept.

Referring to FIG. 4A, a wafer W includes the semiconductor chip 100 and the scribe lane element 120″ that is a region used to perform a sawing process on the semiconductor chips 110.

The semiconductor chips 100 include an IC. For example, the IC can include a memory circuit and/or a logic circuit. The semiconductor chip 100 includes the at least one pad 50 connected to the IC in an active surface of the semiconductor chip 100. The at least one pad 50 can be formed of a metal such as aluminium (Al), copper (Cu), silver (Ag), or gold (Au).

Referring to FIG. 4B, a photosensitive layer 130 like a photoresist is formed on the wafer W.

Referring to FIG. 4C, a photosensitive pattern 130′ is formed on the wafer W by performing an exposure process on the photosensitive layer 130.

Referring to FIGS. 4C and 4D, the scribe lane element 120″ is etched to a predetermined depth by using the photosensitive pattern 130′ as an etching mask. The etching process can be a dry etching process or a wet etching process.

As shown in FIG. 4D, the etching process results in a step between the semiconductor chip 100 and the scribe lane element 120′.

Then, the photosensitive pattern 130′ is removed.

Referring to FIG. 4E, the redistribution element 160 is formed on the scribe lane element 120′ and the semiconductor chip 100.

According to an embodiment, the redistribution element 160 is formed by using electroless plating. That is, the electroless plating is used to form the redistribution element 160 having a predetermined thickness on the semiconductor chip 100 and the scribe lane element 120′.

The electroless plating can include at least one of transition plating, emersion plating, chemical plating, etc. However, the embodiments of the inventive concept are not limited thereto.

The redistribution element 160 can be formed of a metal such as Cu, Ni, Al, Ti, Ta, Cr, W, Co, Au, Ag, Zn, etc.

The wafer W on which the redistribution element 160 is formed is attached onto a support (not shown), and a sawing process to the wafer W is performed to form separated semiconductor chips 100 as shown in FIG. 4E. According to an embodiment, the scribe lane portion 120 having a width less than L2 is formed on a side surface of the semiconductor chip 100 by performing the sawing process on the scribe lane element 120′.

The sawing process is performed on the scribe lane element 120′ to result in the scribe lane region 120 having the width less than L2 so that an area of the redistribution element 160 formed on a side surface of the separated semiconductor chip 100 is exposed to the outside. A width of the remaining scribe lane element 120 may vary according to a thickness of the redistribution element 160 formed on the etched scribe lane element 120′.

For example, referring to FIG. 4F, when the initial thickness of the redistribution element is larger (e.g., L4), the sawing process can result in a greater thickness of the redistribution element 160, and a greater thickness of the scribe lane element 120 remaining on a side surface of the semiconductor chip 100, for example, greater than L2 and less than L4.

Referring to FIG. 4G, when the initial thickness of the redistribution element is smaller (e.g., L6), the sawing process can result in a smaller thickness of the redistribution element 160, and a smaller thickness of the scribe lane element 120 remaining on a side surface of the semiconductor chip 100, for example, less than L6.

According to the following description, the width of the scribe lane element 120 remaining on a side surface of the semiconductor chip 100 is less than L2, but embodiments of the inventive concept are not limited thereto.

Referring to FIG. 4H, the adhesive layer 250 is formed on the semiconductor chip 100 and the redistribution element 160. The adhesive layer 250 can be used to protect the semiconductor chip 100 and stack the sawed semiconductor chips 200 and 300 on the semiconductor chip 100.

Referring to FIG. 4I, the sawed semiconductor chips 200 and 300 are stacked on the intervening adhesive layers 250.

The stacked semiconductor chips 200 and 300 can be homogeneous or heterogeneous with the semiconductor chip 100.

For example, some of the semiconductor chips 100, 200, and 300 can be memory chips, and others can be non-memory chips. According to an embodiment, the semiconductor chips 100, 200, and 300 can be all memory chips. The semiconductor chips 100, 200, and 300 can include flash memory, for example, PRAM, RRAM, FeRAM, MRAM, etc. The semiconductor chips 100, 200, and 300 can have the same size or different sizes according to the types of memory circuits. That is, although the semiconductor chips 100, 200, and 300 having the same width are shown as stacked vertically in FIG. 4I, the embodiments of the inventive concept are not limited thereto, and semiconductor chips having different sizes can be stacked or a plurality of semiconductor chips can be offset from each other and stacked.

The widths of the scribe lane elements 220 and 320 formed on a side surface of each of the semiconductor chips 200 and 300 can be the same or different according to the thicknesses of the redistribution elements 260 and 360.

Referring to FIG. 4J, the signal connection member 500 is formed on a side surface of each of the semiconductor chips 100, 200, and 300 so that the semiconductor chips 100, 200, and 300 that are stacked vertically are electrically connected to each other.

According to an embodiment, a metal layer is formed by performing electroless plating on the redistribution elements 160, 260, and 360 after surface preprocessing is performed. The metal layer acts as a seed layer.

Thereafter, the signal connection member 500 is formed by isotropically growing the metal layer formed on the redistribution elements 160, 260, and 360.

The semiconductor chips 100, 200, and 300 are electrically connected through the signal connection member 500 and the redistribution elements 160, 260, and 360. The metal layer can be, for example, a Ni alloy (Ni—P, Ni—B, etc.), Cu, Co, Au, Ag, Pd, Sn, a Sn alloy, etc.

Referring to FIGS. 4J and 4K, a sawing process on the wafer W is performed to form the separated semiconductor chip 100 on which the sawed semiconductor chips 200 and 300 are stacked vertically and electrically connected through the signal connection member 500.

Referring to FIG. 4L, according to an embodiment, the separated semiconductor chip 100 on which the sawed semiconductor chips 200 and 300 are stacked vertically is disposed on the substrate 10, for example, a PCB, to form the stacked semiconductor device.

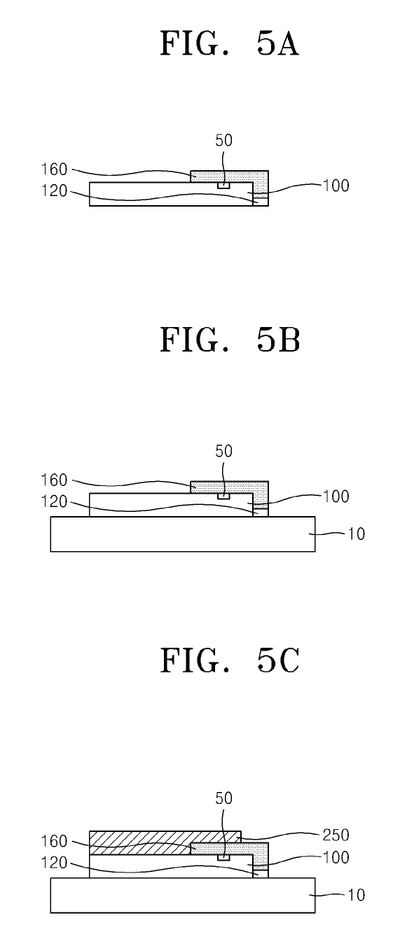

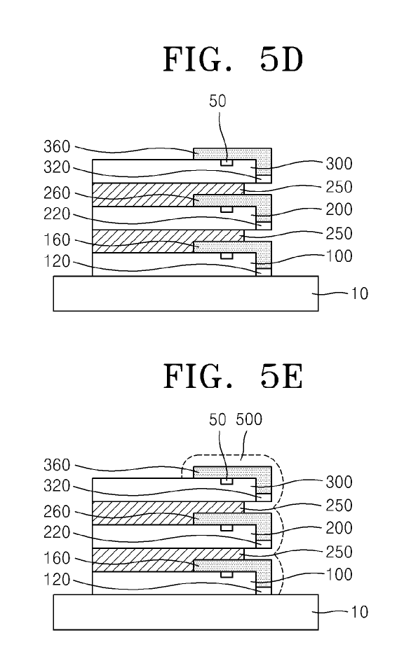

FIGS. 5A through 5E are cross-sectional views illustrating a method of manufacturing a stacked semiconductor device according to an embodiment of the inventive concept.

In FIGS. 4A-4L, the semiconductor chips 200 and 300 are stacked on the wafer W and the signal connection member 500 is formed thereon/ In FIGS. 5A-5E, the semiconductor chips 100, 200, and 300 are stacked on the substrate 10 and the signal connection member 500 is formed thereon.

Referring to FIG. 5A, the semiconductor chip 100 on which a sawing process is performed is prepared. The sawed semiconductor chip 100 includes the scribe lane element 120 having a step on a side surface of the semiconductor chip 100, and the at least one pad 50 that are connected to an IC in an active surface of the sawed semiconductor chip 100.

According to an embodiment, the semiconductor chip 100 is formed by using the method described with reference to FIGS. 4A through 4E.

Referring to FIG. 5B, the semiconductor chip 100 is mounted on the substrate 10. The substrate 10 includes a top surface and a bottom surface. The top surface includes a first metal wire (not shown). The first metal wire is a circuit pattern formed on the substrate 10. The circuit pattern can be formed by using a metal wire such as copper.

According to an embodiment, the substrate 10 includes an external connection terminal (not shown) in the bottom surface thereof. The external connection terminal can be used to connect semiconductor chips stacked on the substrate 10 to devices outside the semiconductor chip stack. The substrate 10 can be, for example, a PCB. The external connection terminal can be, for example a solder ball.

Referring to FIG. 5C, the adhesive layer 250 is formed on the semiconductor chip 100. The adhesive layer 250 can be used to protect the semiconductor chip 100 and stack the sawed semiconductor chips 200 and 300 on the semiconductor chip 100.

Referring to FIG. 5D, the sawed semiconductor chips 200 and 300 are stacked on the intervening adhesive layers 250. According to an embodiment, the sawed semiconductor chips 200 and 300 are formed by using the method described with reference to FIGS. 4A through 4E. The stacked semiconductor chips 200 and 300 can be homogeneous or heterogeneous with the semiconductor chip 100. For example, some of the semiconductor chips 100, 200, and 300 can be memory chips, and others can be non-memory chips. According to an embodiment, the semiconductor chips 100, 200, and 300 can be all memory chips. The semiconductor chips 100, 200, and 300 include, for example, flash memory, PRAM, RRAM, FeRAM, MRAM, etc. The semiconductor chips 100, 200, and 300 can have the same size or different sizes according to types of memory circuits. That is, although the semiconductor chips 100, 200, and 300 having the same width are stacked vertically are shown in FIG. 5D, the embodiments of the inventive concept are not limited thereto, and semiconductor chips having different sizes can be stacked or a plurality of semiconductor chips can be offset from each other and stacked.

The widths of the scribe lane elements 120, 220, and 320 formed a side surface of each of the semiconductor chips 100, 200, and 300 can be the same or different according to the thicknesses of the respective redistribution elements 160, 260, and 360.

Referring to FIG. 5E, the signal connection member 500 is formed on a side surface of each of the semiconductor chips 100, 200, and 300 so that the semiconductor chips 100, 200, and 300 that are stacked vertically are electrically connected to each other.

According to an embodiment, a metal layer is formed by performing electroless plating on the redistribution elements 160, 260, and 360 after surface preprocessing is performed. The metal layer acts as a seed layer.

Thereafter, the signal connection member 500 is formed by isotropically growing the metal layer formed on the redistribution elements 160, 260, and 360.

The semiconductor chips 100, 200, and 300 are electrically connected through the signal connection member 500 and the redistribution elements 160, 260, and 360. The metal layer can be, for example, a Ni alloy (Ni—P, Ni—B, etc.), Cu, Co, Au, Ag, Pd, Sn, a Sn alloy, etc.

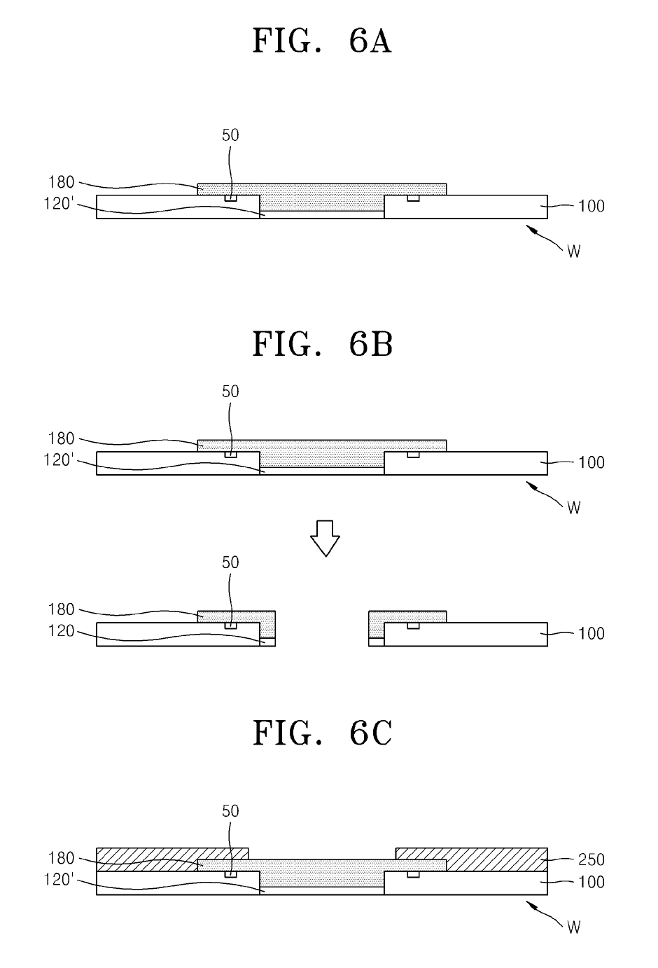

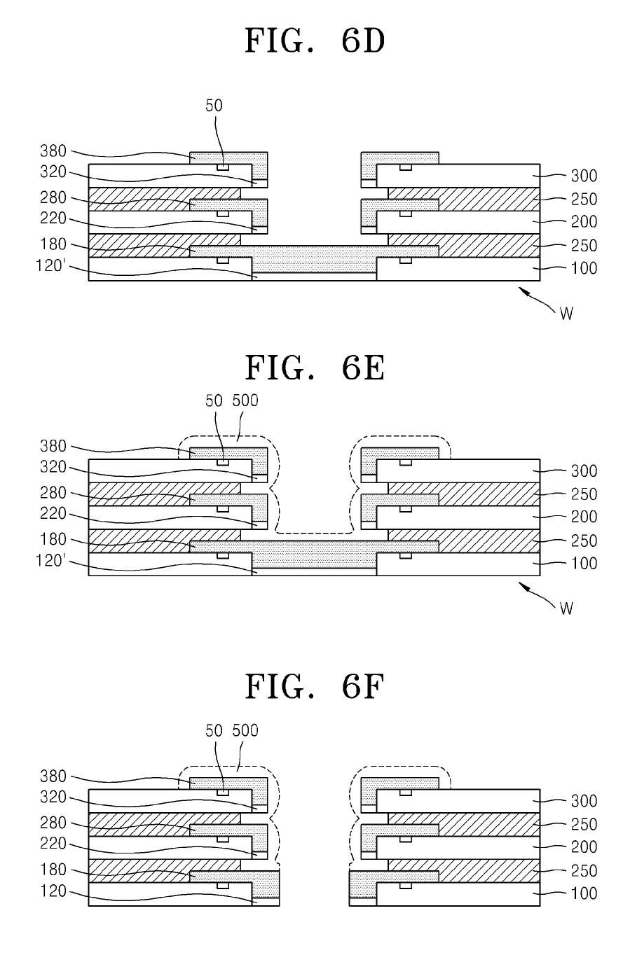

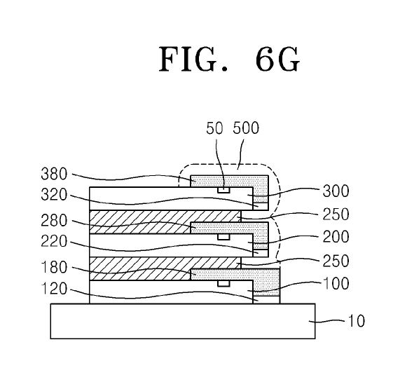

FIGS. 6A through 6F are cross-sectional views illustrating a method of manufacturing a stacked semiconductor device according to an embodiment of the inventive concept.

Referring to FIG. 6A, a step between the scribe lane element 120′ and the semiconductor chip 100 is formed by etching the scribe lane element 120″ to a predetermined depth (see FIGS. 4A through 4D).

The redistribution element 180 is formed on the scribe lane element 120′ that is etched to the predetermined depth and has the step with the semiconductor chip 100.

According to an embodiment, the redistribution element 180 is formed by using electroplating. That is, the redistribution element 180 is formed by using exposure and developing processes after a plating layer is formed by using electroplating. The thickness of the redistribution element 180 formed on the etched scribe lane element 120′ can be selectively adjusted by using electroplating. According to an embodiment, a height of a top surface of the redistribution element 180 formed on the semiconductor chip 100 is not different from a height of a top surface of the redistribution element 180 formed on the scribe lane element 120′.

The redistribution element 180 can be formed of a metal such as Cu, Ni, Al, Ti, Ta, Cr, W, Co, Au, Ag, Zn, etc.

Referring to FIG. 6B, the wafer W on which the redistribution element 180 is formed is attached onto a support (not shown), and a sawing process on the wafer W is performed to form the separated semiconductor chip 100. That is, the scribe lane portion 120 can be formed on a side surface of the semiconductor chip 100 by performing the sawing process on the scribe lane element 120′.

The sawing process is performed to have the scribe lane element 120 remain in order to expose an area of the redistribution element 180 formed on a side surface of the separated semiconductor chip 100 to the outside. According to an embodiment, the scribe lane element 120 having the step with the semiconductor chip 100 remains, which may reduce gaps between the redistribution elements 180, 280, and 380 formed between the semiconductor chips 200 and 300 to be stacked (see FIG. 6D), thereby speeding up the formation of the signal connection member 500 (described further below) and reducing a processing time taken to form the signal connection member 500.

According to an embodiment, electroplating is used to adjust the thickness of the redistribution element 180 formed on the scribe lane element 120′. As a result, the width of the sawed scribe lane element 120′ can be selected.

Referring to FIG. 6C, the adhesive layer 250 is formed on the semiconductor chip 100 and the redistribution element 180.

The adhesive layer 250 can be used to protect the semiconductor chip 100 and stack the sawed semiconductor chips 200 and 300 on the semiconductor chip 100.

Referring to FIG. 6D, the sawed semiconductor chips 200 and 300 are stacked on the intervening adhesive layers 250. The sawed semiconductor chips 200 and 300 are the same as the sawed semiconductor chip 100 described with reference to FIG. 6B.

The stacked semiconductor chips 200 and 300 can be homogeneous or heterogeneous with the semiconductor chip 100. For example, some of the semiconductor chips 100, 200, and 300 can be memory chips, and others can be non-memory chips. According to an embodiment, the semiconductor chips 100, 200, and 300 can be all memory chips. The semiconductor chips 100, 200, and 300 include, for example, flash memory, PRAM, RRAM, FeRAM, MRAM, etc. The semiconductor chips 100, 200, and 300 can be the same size or different sizes according to the types of memory circuits.

Although the semiconductor chips 100, 200, and 300 having the same width are stacked vertically in FIG. 6D, the embodiments of the inventive concept are not limited thereto, and semiconductor chips having different sizes can be stacked or a plurality of semiconductor chips can be offset and stacked on each other.

Referring to FIG. 6E, the signal connection member 500 is formed along the redistribution elements 180, 280, and 380 formed on a side surface of the semiconductor chips 100, 200, and 300 so that the circuits of the semiconductor chips 100, 200, and 300 that are stacked vertically are electrically connected.

In more detail, according to an embodiment, a metal layer is formed by performing electroless plating on the redistribution elements 180, 280, and 380 after surface preprocessing is performed.

Thereafter, the signal connection member 500 is formed by isotropically growing the metal layer formed in the redistribution elements 180, 280, and 380.

According to an embodiment, the semiconductor chips 100, 200, and 300 are electrically connected through the signal connection member 500 and the redistribution elements 180, 280, and 380. The metal layer can be, for example, a Ni alloy (Ni—P, Ni—B, etc.), Cu, Co, Au, Ag, Pd, Sn, a Sn alloy, etc.

Referring to FIGS. 6E and 6F, a sawing process on the wafer W is performed to form the separated semiconductor chip 100 on which the sawed semiconductor chips 200 and 300 are stacked vertically and electrically connected through the signal connection member 500.

Referring to FIG. 6G, according to an embodiment, the separated semiconductor chip 100 on which the sawed semiconductor chips 200 and 300 are stacked vertically is disposed on the substrate 10, for example, a PCB, to form the stacked semiconductor device.

In this regard, although the semiconductor chips 200 and 300 are stacked on the wafer W and the signal connection member 500 is formed thereon, in an alternative embodiment, the semiconductor chips 100, 200, and 300 are stacked on a PCB and the signal connection member 500 is formed thereon.

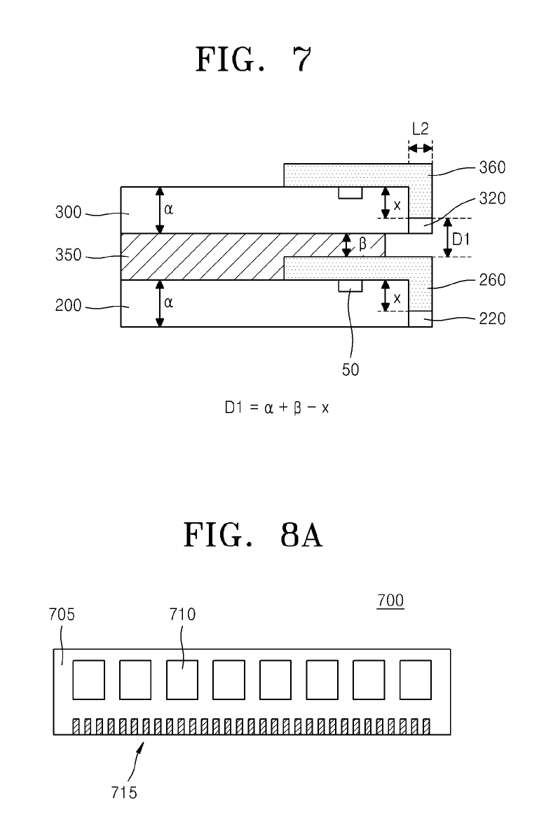

FIG. 7 is a cross-sectional view illustrating heights of the redistribution elements 260 and 360 on which the signal connection member 500 is formed according to an embodiment of the inventive concept.

Referring to FIG. 7, the scribe lane elements 220 and 320 are etched to a predetermined depth by using an etching process and form steps x with the semiconductor chips 200 and 300.

The redistribution elements 260 and 360 formed on the semiconductor chips 200 and 300 and the scribe lane elements 220 and 320 have top surfaces having the same height, and thus the signal connection member 500 (see FIG. 4J or 6E) having a height higher than at least D1 is formed in order to electrically connect the semiconductor chips 200 and 300.

In more detail, unlike where a scribe lane element is removed or a scribe lane element having no step between the semiconductor chips 200 and 300 remains during a process of sawing the semiconductor chips 200 and 300, the redistribution elements 260 and 360 are formed on the scribe lane elements 220 and 320 forming the steps x with the semiconductor chips 200 and 300.

Therefore, a gap D1 (D1=α+β−x, where α denotes a thickness of a semiconductor chip, β denotes a thickness of an adhesive layer, and x denotes a step between the semiconductor chip and a scribe lane element) between the redistribution elements 260 and 360 formed on a surface of each of the semiconductor chips 200 and 300 may be reduced, thereby reducing a processing time taken to form the signal connection member 500 (see FIG. 4J or 6E).

In FIG. 7, the semiconductor chips 200 and 300 have the same size, and the steps x formed between the semiconductor chips 200 and 300 and the scribe lane elements 220 and 320, respectively, are the same. However, when the semiconductor chips 200 and 300 have different sizes, and the steps x formed between the semiconductor chips 200 and 300 and the scribe lane elements 220 and 320, respectively, are different. In addition, the gap between the redistribution elements 260 and 360 in which the signal connection member 500 is formed in order to electrically connect the semiconductor chips 200 and 300 is further reduced compared to when there is no such step therebetween, thereby reducing the processing time taken to form the signal connection member 500.

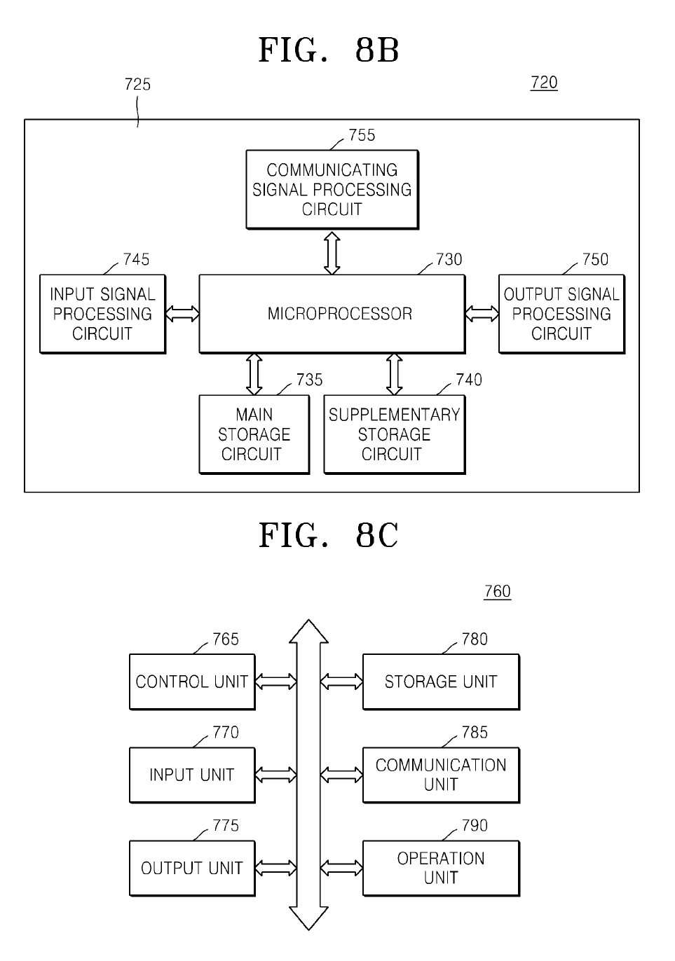

FIG. 8A is a plan view of a semiconductor module 700 including a stacked semiconductor device according to an embodiment of the inventive concept.

Referring to FIG. 8A, the semiconductor module 700 includes a module substrate 705, a plurality of semiconductor packages 710 disposed on the module substrate 705, and module contact terminals 715 formed in parallel to each other on an edge of the module substrate 705 and electrically connected to the semiconductor packages 710.

The module substrate 705 can be, for example, a PCB. Both surfaces of the module substrate 705 may be used. That is, the semiconductor packages 710 can be disposed on both a front surface and a rear surface of the module substrate 705.

Although the 8 semiconductor packages 710 are disposed on the front surface of the module substrate 705 in FIG. 8A, the embodiments of the inventive concept are not limited thereto. According to an embodiment, one semiconductor module includes 8 semiconductor devices or semiconductor packages.

A semiconductor module may further include an additional semiconductor device or semiconductor package to control 8 semiconductor devices or semiconductor packages.

Thus, the number of the semiconductor devices 710 or the semiconductor packages 715 is not limited to what is shown on the semiconductor module 700 of FIG. 8A.

At least one of the semiconductor packages 710 may be a package of the stacked semiconductor devices 1000 and 2000 of embodiments of the inventive concept. Alternatively, at least one of the semiconductor packages 710 may be a semiconductor device that is not packaged.

According to an embodiment, the module contact terminals 715 are formed of a metal and have an oxidation resistance. The module contact terminals 715 can be set in various ways according to the standard specification of the semiconductor module 700. Thus, the number of module contact terminals 715 may vary.

FIG. 8B is a block diagram of an electronic circuit board 720 according to an embodiment of the inventive concept.

Referring to FIG. 8B, the electronic circuit board 720 includes a microprocessor 730 disposed on a circuit board 725, a main storage circuit 735 and a supplementary storage circuit 740 that communicate with the microprocessor 730, an input signal processing circuit 745 that sends a command to the microprocessor 730, an output signal processing circuit 750 that receives the command from the microprocessor 730, and a communicating signal processing circuit 755 that communicates an electrical signal with other circuit boards. Arrows may be understood to mean paths for transferring electrical signals.

The microprocessor 730 can receive and process various electrical signals, output results, and control other elements of the electronic circuit board 720. The microprocessor 730 can be to be, for example, a central processing unit (CPU) and/or a main control unit (MCU). The main storage circuit 735 can temporarily store data that is always or frequently required by the microprocessor 730 or data before and after processing.

According to an embodiment, the main storage circuit 735 is able to respond quickly and is configured as a semiconductor memory. In more detail, the main storage circuit 735 can be a semiconductor memory called a cache, and can be configured as a static random access memory (SRAM), a dynamic random access memory (DRAM), a resistive random access memory (RRAM), or other application semiconductor memories, for example, a utilized RAM, ferro-electric RAM, fast cycle RAM, phase changeable RAM, magnetic RAM, etc.

According to an embodiment, the main storage circuit 735 includes at least one of stacked semiconductor devices according to the embodiments of the inventive concept.

The supplementary storage circuit 740 is a mass storage memory device, and can be a non-volatile semiconductor memory such as a flash memory or a hard disk drive using a magnetic field. Alternatively, the supplementary storage circuit 740 can be a compact disk drive using light. According to an embodiment, the supplementary storage circuit 740 is not required to have a fast speed, compared with the main storage circuit 735, but can be used to store mass storage data. The supplementary storage circuit 740 can include stacked semiconductor devices according to the embodiments of the inventive concept.

According to an embodiment, the signal processing circuit 745 converts an external command into an electrical signal or transfers an electrical signal transferred from the outside to the microprocessor 730. The external command or the electrical signal can be, for example, a motion command, an electrical signal to be processed, or data to be stored. The signal processing circuit 745 can be a terminal signal processing circuit that processes a signal transmitted from, for example, a keyboard, a mouse, a touch pad, an image sensing device or one of various sensors, an image signal processing circuit that processes an image signal input of a scanner or a camera, one of various sensors, an input signal interface, etc. The signal processing circuit 745 can include stacked semiconductor devices according to the embodiments of the inventive concept.

The output signal processing circuit 750 can be an element for transmitting electrical signals processed by the microprocessor 730 to the outside. For example, the output signal processing circuit 750 can be a graphic card, an image processor, an optical converter, a beam panel card, an interface circuit having various functions, etc. The output signal processing circuit 750 can include stacked semiconductor devices according to the embodiments of the inventive concept.

The communicating signal processing circuit 755 is an element for directly communicating an electrical signal of another electronic system or another circuit board without the signal processing circuit 745 or the output signal processing circuit 750. For example, the communicating signal processing circuit 755 can be a modem of a PC, a LAN card, one of various interface circuits, etc. The communicating signal processing circuit 755 can include stacked semiconductor devices according to the embodiments of the inventive concept.

FIG. 8C is a block diagram of an electronic system 760 according to an embodiment of the inventive concept.

Referring to FIG. 8C, the electronic system 760 of the present embodiment includes a control unit 765, an input unit 770, an output unit 775, and a storage unit 780, and can further include a communication unit 785 and/or an operation unit 790.

The control unit 765 controls the electronic system 760 and the elements. The control unit 765 can be, for example, a CPU or an MCU. The control unit 765 can include stacked semiconductor devices according to the embodiments of the inventive concept.

The input unit 770 sends an electrical command signal to the control unit 765. The input unit 770 can be a keyboard, a keypad, a mouse, a touch pad, an image sensing device like a scanner, or one of various other input sensors. The input unit 770 includes stacked semiconductor devices according to the embodiments of the inventive concept.

The output unit 775 receives the electrical command signal from the control unit 765 and outputs a processing result of the electronic system 760. The output unit 775 can be, for example, a monitor, a printer, a beam irradiator, or one of various other mechanical devices. The output unit 775 includes stacked semiconductor devices according to the embodiments of the inventive concept.

The storage unit 780 is an element for temporarily or permanently storing an electrical signal that is to be processed or is processed by the control unit 765. The storage unit 780 can be physically and electrically connected or coupled to the control unit 765. The storage unit 780 can be a semiconductor memory, a magnetic storage device like a hard disk, an optical storage device like a compact disk, or a server having another data storage function. The storage unit 780 includes stacked semiconductor devices according to the embodiments of the inventive concept.

The communication unit 785 receives the electrical command signal from the control unit 765 and sends or receives an electrical signal to or from another electronic system. The communication unit 785 can be a wired transmission/reception device, like a modem or a LAN card, a wireless transmission/reception device, like a Wibro interface, an infrared port, etc. The communication unit 785 includes stacked semiconductor devices according to the embodiments of the inventive concept.

The operation unit 790 performs a physical or mechanical operation according to a command of the control unit 765. For example, the operation unit 790 can be an element for performing the mechanical operation, such as a plotter, an indicator, an up/down operator, etc.

The electronic system 760 of the present embodiment can be a computer, a network server, a networking printer or scanner, a wireless controller, a mobile communication terminal, an exchanger, or an electronic device that performs a programmed operation.

While the inventive concept has been particularly shown and described with reference to exemplary embodiments thereof, it will be understood that various changes in form and details may be made therein without departing from the spirit and scope of the following claims.

What is claimed is:

1. A stacked semiconductor device comprising:
a plurality of semiconductor chips stacked on each other;
a plurality of scribe lane elements each forming a step with a semiconductor chip of the plurality of semiconductor chips and respectively formed on a side surface of each of the plurality of semiconductor chips;
a redistribution element respectively formed on each of the plurality of semiconductor chips and the scribe lane elements; and
a signal connection member formed on the side surface of each of the plurality of semiconductor chips and electrically connecting the redistribution elements to each other.

2. The stacked semiconductor device of claim 1, wherein the plurality of semiconductor chips are homogeneous or heterogeneous with each other.

3. The stacked semiconductor device of claim 1, wherein the redistribution elements covers at least one pad formed in a surface of each of the plurality of semiconductor chips and are respectively electrically connected to each of the plurality of semiconductor chips.

4. The stacked semiconductor device of claim 1, wherein the redistribution elements are electro plating or electroless plating layers.

5. The stacked semiconductor device of claim 1, wherein a thickness of the redistribution elements on the scribe lane elements is greater than a thickness of the redistribution elements on each of the plurality of semiconductor chips.

6. The stacked semiconductor device of claim 1, wherein the signal connection member is an electroless plating layer.

7. The stacked semiconductor device of claim 1, wherein the plurality of semiconductor chips are mounted on a substrate, the signal connection member contacts the substrate, and the plurality of semiconductor chips and the substrate are electrically connected.

8. The stacked semiconductor device of claim 7, wherein the substrate comprises an external connection terminal connected to an external device.

9. The stacked semiconductor device of claim 8, wherein the external connection terminal is a solder ball.

10. The stacked semiconductor device of claim 1, further comprising: an adhesive layer formed on each of the plurality of semiconductor chips and adhering the plurality of semiconductor chips that are stacked on each other.

11. A stacked semiconductor device comprising:
a first semiconductor chip comprising a first scribe lane element having a step on a side surface of the first semiconductor chip and at least one pad connected to an integrated circuit (IC) in an active surface of the first semiconductor chip;
a first redistribution element formed on the first semiconductor chip;
at least one second semiconductor chip staked on the first semiconductor chip and comprising a second scribe lane element having a step on a side surface of the second semiconductor chip and at least one pad connected to an IC in an active surface of the at least one second semiconductor chip;
a second redistribution element formed on the at least one second semiconductor chip; and
a signal connection member for electrically connecting the first redistribution element with the second redistribution element.

12. The stacked semiconductor device of claim 11, wherein the first redistribution element and the second redistribution element are electro plating layers or electroless plating layers.

13. The stacked semiconductor device of claim 11, wherein a thickness of the first redistribution element formed on the first scribe lane element is greater than a thickness of the first redistribution element formed on the active surface of the first semiconductor chip.

14. The stacked semiconductor device of claim 11, wherein a thickness of the second redistribution element formed on the second scribe lane element is greater than a thickness of the second redistribution element formed on the active surface of the second semiconductor chip.

15. The stacked semiconductor device of claim 11, wherein the signal connection member is an electroless plating layer.

16. A stacked semiconductor device comprising:
a first semiconductor chip comprising a first scribe lane element forming a step with a side surface of the first semiconductor chip;
a first redistribution element formed on a top surface of the first semiconductor chip and extending onto the first scribe lane element;
at least one second semiconductor chip stacked on the first semiconductor chip and comprising a second scribe lane element forming a step with a side surface of the second semiconductor chip;
a second redistribution element formed on a top surface of the at least one second semiconductor chip and extending onto the second scribe lane element; and
a signal connection member for electrically connecting the first redistribution element with the second redistribution element.

17. The stacked semiconductor device of claim 16, wherein a width of the first scribe lane element is greater than a width of the second scribe lane element.

18. The stacked semiconductor device of claim 17, wherein a width of the first redistribution element on the first scribe lane element is greater than a width of the second redistribution element on the second scribe lane element.

19. The stacked semiconductor device of claim 17, wherein the widths of the first and second redistribution elements on the first and second scribe lane elements respectively correspond to the widths of the first and second scribe lane elements.

20. The stacked semiconductor device of claim 16, wherein the first and second redistribution elements respectively cover at least one pad formed in the top surface of each of the first and second semiconductor chips and are respectively electrically connected to the first and second semiconductor chips.
